(19) United States
(12) Patent Application Publication
(10) Pub. No.: US 2023/0273266 A1
(43) Pub. Date: Aug. 31, 2023

(54) BATTERY DETERIORATION DEGREE PREDICTION APPARATUS

(71) Applicant: SUBARU CORPORATION, Tokyo (JP)

(72) Inventor: Yusuke OKUBO, Tokyo (JP)

(21) Appl. No.: 18/166,815

(22) Filed: Feb. 9, 2023

(30) Foreign Application Priority Data
Feb. 28, 2022 (JP) 2022-029237

(51) Int. Cl. G01R 31/392; B60W 10/26; G01R 31/367; G01R 31/36

(52) U.S. Cl. CPC G01R 31/392; B60W 10/26; G01R 31/3648; G01R 31/367

(57) ABSTRACT

A battery deterioration degree prediction apparatus comprising an obtaining unit and a controller. The obtaining unit obtains one or more histories of types of operation parameters for a target battery and reference batteries and a degree of deterioration of the reference batteries. The controller predicts a degree of deterioration of the target battery. Using map data where groups into which the reference batteries are classified and coefficients representing rates of change in the degrees of deterioration of the reference batteries are associated with each other. The groups in the map data are classified by a trend of histories of a first group parameter included in the types of operation parameters. The coefficients in the map data are derived based on the histories for the reference batteries and the degrees of deterioration of the reference batteries belonging to one of the groups that is associated with the coefficients.

### CROSS REFERENCE TO RELATED APPLICATIONS

The present application claims priority from Japanese Patent Application No. 2022-029237 filed on Feb. 28, 2022, the entire contents of which are hereby incorporated by reference.

### BACKGROUND

The disclosure relates to a battery deterioration degree prediction apparatus.

International Patent Application Publication WO 2017/033311 A1 describes an apparatus configured to estimate the degree of deterioration of a battery provided in a vehicle by managing cycle deterioration that occurs due to charging/discharging and storage deterioration that occurs regardless of charging/discharging.

### SUMMARY

An aspect of the disclosure provides a battery deterioration degree prediction apparatus. The battery deterioration degree prediction apparatus includes an obtaining unit and a controller. The obtaining unit is configured to obtain a history of types of operation parameters for a target battery, histories of the types of operation parameters for reference batteries, and a degree of deterioration of the reference batteries. The target battery is a battery for traveling provided in a target vehicle. The reference batteries are each a battery for traveling provided in a vehicle different from the target vehicle. The controller is configured to predict degrees of deterioration of the target battery. The controller is configured to predict the degree of deterioration of the target battery using map data in which groups into which the reference batteries are classified and coefficients representing rates of change in the degrees of deterioration of the reference batteries are associated with each other. The groups in the map data are classified by a trend of histories of a first group parameter included in the types of operation parameters. The coefficients in the map data are derived based on the histories for the reference batteries and the degrees of deterioration of the reference batteries belonging to one of the groups that is associated with the coefficients.

An aspect of the disclosure provides a battery deterioration degree prediction apparatus. The battery deterioration degree prediction apparatus includes circuitry. The circuitry is configured to obtain a history of types of operation parameters for a target battery, histories of the types of operation parameters for reference batteries, and degrees of deterioration of the reference batteries, the target battery being a battery for traveling provided in a target vehicle, the reference batteries each being a battery for traveling provided in a vehicle different from the target vehicle. The circuitry is configured to predict a degree of deterioration of the target battery. The circuitry is configured to predict the degree of deterioration of the target battery using map data in which groups into which the reference batteries are classified and coefficients representing rates of change in the degree of deterioration of the reference batteries are associated with each other. The groups in the map data are classified by a trend of histories of a first group parameter included in the types of operation parameters. The coefficients in the map data are derived based on the histories for the reference batteries and the degrees of deterioration of the reference batteries belonging to one of the groups that is associated with the coefficients.

### BRIEF DESCRIPTION OF THE DRAWINGS

The accompanying drawings are included to provide a further understanding of the disclosure and are incorporated in and constitute a part of this specification. The drawings illustrate an embodiment and, together with the specification, serve to describe the principles of the disclosure.

FIG. 1 is a schematic diagram illustrating the configuration of a system according to an embodiment for predicting the degree of deterioration of a target battery;

FIG. 2 is a block diagram illustrating a battery deterioration degree prediction apparatus and the fundamental parts of vehicles illustrated in FIG. 1;

FIG. 3 is a diagram explaining the current frequency of reference batteries and a target battery;

FIG. 4 is a diagram illustrating first map data for obtaining the degree of storage deterioration;

FIG. 5 is a diagram explaining an example of a method of deriving a coefficient in the first map data;

FIG. 6 is a diagram illustrating second map data for obtaining the degree of cycle deterioration;

FIG. 7 is a diagram explaining an example of a method of deriving a coefficient in the second map data;

FIG. 8 is a data table indicating the relationship between an inactive current frequency and a weighting coefficient;

FIG. 9 is a flowchart illustrating a procedure of a process of predicting the degree of deterioration; and

FIG. 10 is a diagram illustrating an example of a method of calculating the current integration acceleration.

### DETAILED DESCRIPTION

In vehicles traveling on electric power, it is desirable to accurately predict the degree of deterioration of a battery for traveling. However, the transition of the degree of deterioration of the battery for traveling differs depending on the actual usage state of the electric vehicle.

The disclosure provides a battery deterioration degree prediction apparatus capable of highly accurately predicting the degree of deterioration of a battery for traveling.

In the following, an embodiment of the disclosure is described in detail with reference to the accompanying drawings. Note that the following description is directed to an illustrative example of the disclosure and not to be construed as limiting to the disclosure. Factors including, without limitation, numerical values, shapes, materials, components, positions of the components, and how the components are coupled to each other are illustrative only and not to be construed as limiting to the disclosure. Further, elements in the following example embodiment which are not recited in a most-generic independent claim of the disclosure are optional and may be provided on an as-needed basis. The drawings are schematic and are not intended to be drawn to scale. Throughout the present specification and the drawings, elements having substantially the same function and configuration are denoted with the same numerals to avoid any redundant description.

In the present specification, among batteries for traveling that are provided in vehicles 1 and 2, the battery for traveling whose degree of deterioration is to be predicted will be referred to as a target battery 111. Also, a battery for traveling whose history and the like are referenced will be referred to as a reference battery 112.

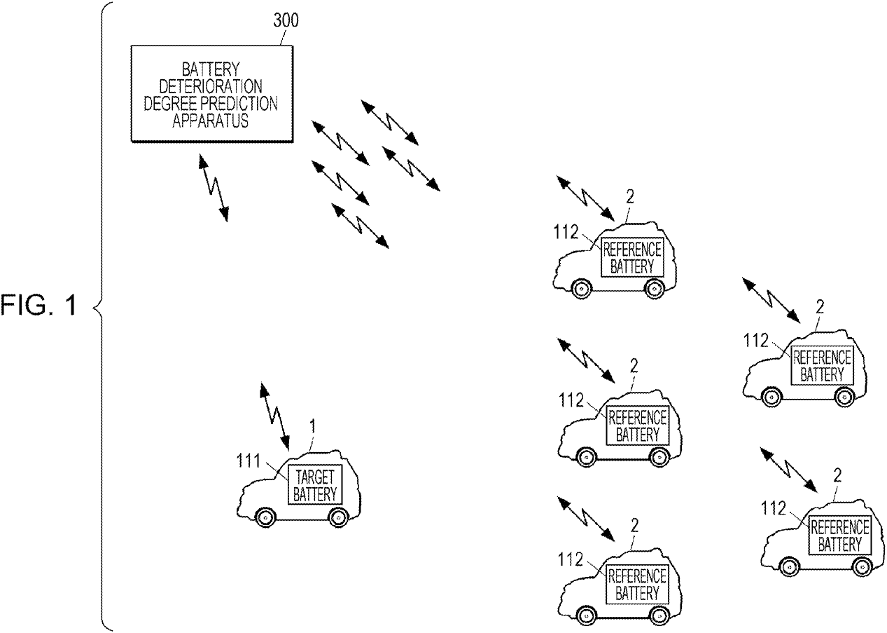

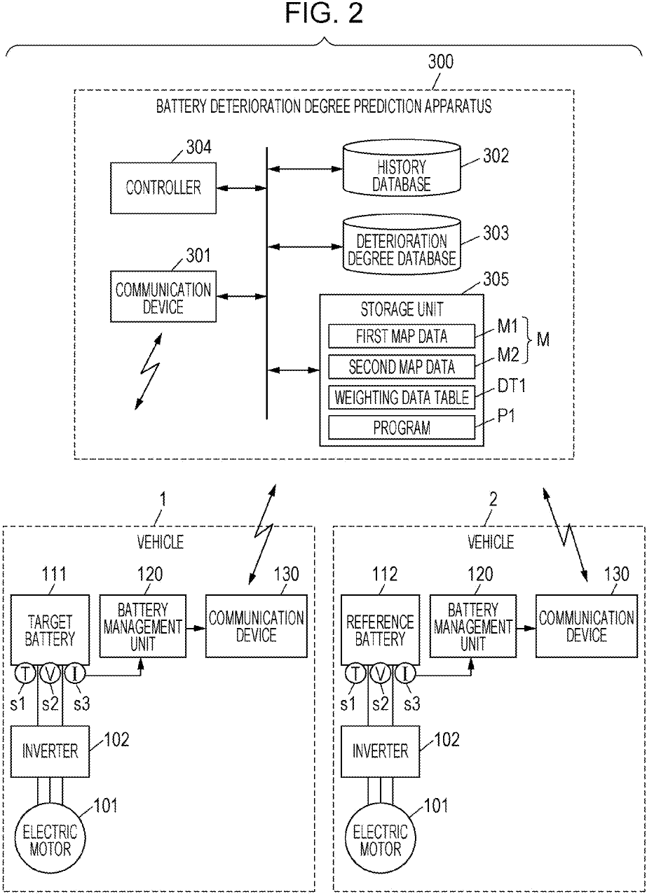

FIG. 1 is a schematic diagram illustrating the configuration of a system for predicting the degree of deterioration of the target battery. FIG. 2 is a block diagram illustrating a battery deterioration degree prediction apparatus and the main parts of vehicles illustrated in FIG. 1.

As illustrated in FIG. 1, the system of the present embodiment includes the vehicle 1 with the target battery 111, the vehicles 2 each with the reference battery 112, and a battery deterioration degree prediction apparatus 300 which communicates with the vehicles 1 and 2 to predict the degree of deterioration of the target battery 111.

The target battery 111 and the reference batteries 112 are rechargeable batteries that supply power to an electric motor 101 (FIG. 2) which generates the running power of the vehicles 1 and 2. The batteries for traveling (111 and 112) are, for example, lithium ion secondary batteries, nickel-metal hydride secondary batteries, and the like, but as long as power for driving the electric motor 101 can be accumulated, any kind of rechargeable battery may be used.

The vehicle 1 and the vehicles 2 may be vehicles of the same type, and the target battery 111 and the reference batteries 112 may be batteries of the same model (same type and same capacity).

Of the batteries for traveling (111 and 112) provided in the vehicles 1 and 2, which is regarded as the target battery 111 and which are regarded as the reference batteries 112 are arbitrary. That is, the degree of deterioration of the target battery 111 may be predicted by regarding the vehicle 1 and the target battery 111 illustrated in FIG. 1 as the vehicle 2 and the reference battery 112 and regarding any one of the vehicles 2 and of the reference batteries 112 illustrated in FIG. 1 as the vehicle 1 and the target battery 111. As mentioned above, the target battery 111 and the reference batteries 112 are conceptually interchangeable. By performing such interchanges, the degree of deterioration of all the batteries for traveling (111 and 112) may be predicted.

As illustrated in FIG. 2, each vehicle 2 includes the reference battery 112, the electric motor 101, an inverter 102, a battery management unit 120 which manages the reference battery 112, and a communication device 130 which communicates with the battery deterioration degree prediction apparatus 300. The battery management unit 120 has sensors s1 to s3 configured to detect the respective operation parameters (such as current, voltage, and temperature) of the reference battery 112. The battery management unit 120 receives the detection values of the sensors s1 to s3 and determines whether to permit discharging or charging of the reference battery 112. The battery management unit 120 sends the detection values of the sensor s1 to s3 to the communication device 130.

The battery management unit 120 calculates the degree of deterioration (state of health or SOH) of the reference battery 112 based on the detection values of the sensor s1 to s3. The degree of deterioration is not always calculable; for example, when the reference battery 112 becomes fully charged, the degree of deterioration can be calculated by comparing the current amount of charge and the initial amount of charge. Having calculated the degree of deterioration, the battery management unit 120 updates deterioration degree data managed by itself.

The communication device 130 sends the detection values of the sensors s1 to s3 and the degree of deterioration to the battery deterioration degree prediction apparatus 300. The communication device 130 may send the above detection values to the battery deterioration degree prediction apparatus 300 in real time, or may once accumulate the above detection values and then send them to the battery deterioration degree prediction apparatus 300. As means of communication, various means may be employed, such as wireless communication, wired communication, means of moving data by physically passing a storage medium, and so forth.

The vehicle 1 is the same as the vehicles 2 except that the name of the battery for traveling changes from “reference battery 112” to “target battery 111”. If the target battery 111 does not need to play the role of the reference battery 112, the vehicle 1 need not calculate or send the degree of deterioration.

The battery deterioration degree prediction apparatus 300 includes a communication device 301 which receives data sent from the vehicles 1 and 2, a history database 302 which stores the received history information, a deterioration degree database 303 which stores the received degree-of-deterioration information, a controller 304 which predicts the degree of deterioration of the target battery 111 (estimates the degree of deterioration in the future) based on the history information and the degree-of-deterioration information, and a storage unit 305. In one embodiment, the communication device 301 corresponds to an example of an obtaining unit according to the disclosure.

In the history database 302, history information of the detection values of the sensors s1 to s3 of the vehicles 1 and 2 is stored. The history information means that each detection value is time-series information linked to data indicating the measurement time. In the history database 302, the detection values of the sensors s1 to s3 are stored in a way that whether each detection value is the detection value of any of the vehicles 1 and 2 is identifiable. In one example, each of the above detection values is stored in conjunction with a vehicle identification (ID) that identifies a corresponding one of the vehicles 1 and 2. The detection values stored in the history database 302 are detection values obtained while the system in each of the vehicles 1 and 2 is operating, and need not include information while the system in each of the vehicles 1 and 2 is not operating.

The deterioration degree database 303 stores information on the degree of deterioration of the reference batteries 112 of the vehicles 2. The degree-of-deterioration information is stored in conjunction with, for example, a vehicle ID that identifies each of the vehicles 2 in a way that whether each item of information is the degree of deterioration of any of the vehicles 2 is identifiable. When updated degree-of-deterioration information is sent from a certain vehicle 2, the old degree-of-deterioration information of the reference battery 112 of that vehicle 2 may be deleted from the deterioration degree database 303, and the updated information alone may be stored.

In one example, the controller 304 is a calculation processing unit, and generates map data M for calculating the degree of deterioration in the storage unit 305 based on the information in the history database 302 and the information in the deterioration degree database 303. The map data M in the storage unit 305 includes first map data M1 for calculating the degree of storage deterioration and second map data M2 for calculating the degree of cycle deterioration.

The storage unit 305 further stores a weighting data table DT1 in which a weighting coefficient is stored, which is used for adding up the degree of storage deterioration and the degree of cycle deterioration, and a program P1 for a later-described process of predicting the degree of deterioration.

### Actual Usage States of Batteries for Traveling

The deterioration of the batteries for traveling (111 and 112) is classified into cycle deterioration that represents deterioration due to charging/discharging and storage deterioration that represents deterioration during storage. Cycle deterioration is deterioration due to charging/discharging, and storage deterioration is deterioration that occurs regardless of charging/discharging. The degree of deterioration of the above two is called the degree of cycle deterioration and the degree of storage deterioration. The value obtained by combining the degree of cycle deterioration and the degree of storage deterioration corresponds to the degree of overall deterioration (SOH). The degree of overall deterioration indicates the ratio of the fully charged capacity at a given time to the initial fully charged capacity.

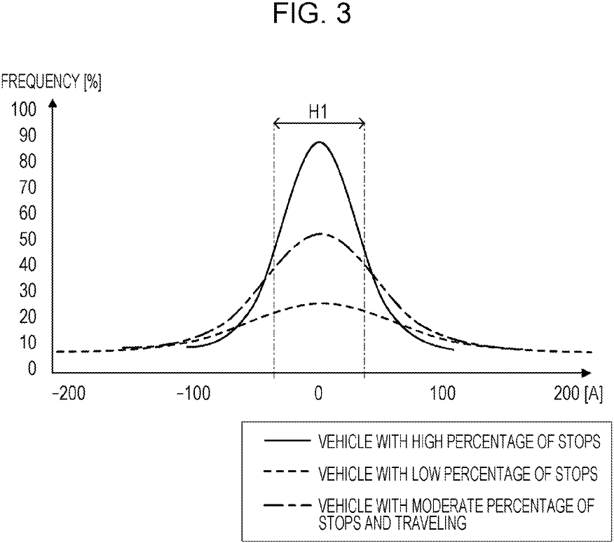

FIG. 3 is a diagram explaining the current frequency of the reference batteries and the target battery. The vehicles 2 travel in various modes, and the actual usage states of the reference batteries 112 are not uniform. However, as illustrated in FIG. 3, even if the actual usage states of the reference batteries 112 are different, their current frequencies are often distribution curves approximating a normal distribution centered on 0 A. Therefore, the actual usage states of the reference batteries 112 can be determined from distribution curves in a range close to 0 A (such as -30 A to 30 A) among the distribution curves of the current frequencies. Here, a current frequency indicates the percentage of time that the current is output (for + sign) or input (for - sign). The current frequency can be calculated from the history of the current.

As indicated by the solid line in FIG. 3, in the reference battery 112 provided in the vehicle 2 having a high percentage of stops, the graph line of the current frequency has a high mountain shape. Meanwhile, as indicated by the dashed line in FIG. 3, in the reference battery 112 provided in the vehicle 2 having a low percentage of stops, the graph line of the current frequency has a low mountain shape. Moreover, as indicated by the dash-dotted line in FIG. 3, in the reference battery 112 provided in the vehicle 2 where both the percentage of stops and the percentage of traveling are moderate, the graph line of the current frequency has a moderate mountain shape. As described above, the actual usage states of the reference batteries 112 can be classified into the case where the percentage of stops is high, the case where the percentage of stops is low, and the case in between.

Here, an inactive current frequency is defined as a current frequency representing the above classification. The inactive current frequency means the frequency at which the reference battery 112 is in a state close to the storage state (inactive state). In one example, the inactive current frequency means the percentage of time that the input current or the output current of the reference battery 112 is within a certain small current range H1 (FIG. 3, such as -30 A to 30 A). The reference battery 112 being inactive means that the vehicle 2 is stopped or in a low speed driving state. The inactive current frequency corresponds to the area of a portion below the distribution curves in the current range H1 of the current frequency graph illustrated in FIG. 3.

Hereinafter, the actual usage states of the reference batteries 112 are classified into the case where the percentage of stops is high, the case where the percentage of stops is intermediate, and the case where the percentage of stops is low, based on the classification as follows: inactive current frequency ≥ first threshold (such as 75%); first threshold > inactive current frequency > second threshold (such as 25%); and second threshold ≥ inactive current frequency. The first threshold is set to a value greater than the second threshold.

In the case where the percentage of stops is high, that is, in the reference battery 112 where the inactive current frequency ≥ the first threshold, storage deterioration mainly appears predominantly as the deterioration of the reference battery 112. In the case where the percentage of stops is low, that is, in the reference battery 112 where the second threshold ≥ the inactive current frequency, cycle deterioration mainly appears predominantly as the deterioration of the reference battery 112. In the case where the percentage of stops is not high or low, that is, in the reference battery 112 where the first threshold > the inactive current frequency > the second threshold, both storage deterioration the cycle deterioration appear as the deterioration of the reference battery 112.

### First Map Data

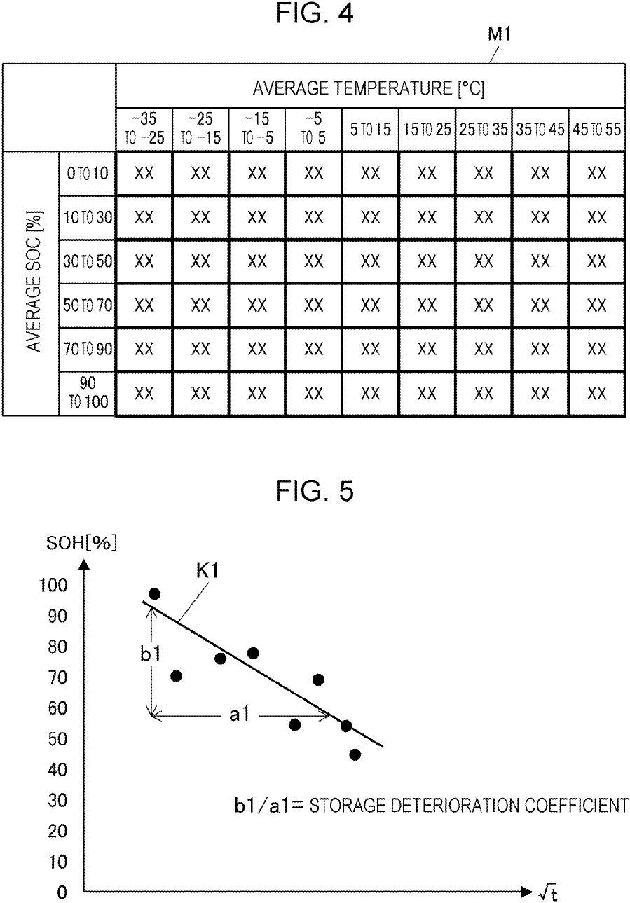

FIG. 4 is a diagram illustrating first map data for obtaining the degree of storage deterioration.

The first map data M1 is map data for obtaining the degree of storage deterioration. The first map data M1 is generated by the controller 304 based on the information in the history database 302 and the information in the deterioration degree database 303.

The first map data M1 corresponds to data where groups into which the reference batteries 112 are classified are associated with storage deterioration coefficients each indicating the rate of change in the degree of deterioration of the reference batteries 112. In FIG. 4, each bold frame corresponds to one group, and the storage deterioration coefficient of that group is stored within the bold frame. “XX” in FIG. 4 indicates the storage deterioration coefficient of each group.

The groups in the first map data M1 correspond to the reference batteries 112 classified by trends of a certain group parameter (voltage and temperature, which correspond to examples of a first group parameter according to the disclosure) among types of operation parameters (current, voltage, and temperature) of the reference batteries 112. In the present embodiment, the average state of charge (SOC) is adopted as the trend of voltage, and the average temperature is adopted as the trend of temperature. The SOC is determined from the voltage. The controller 304 calculates the average SOC and the average temperature from the history information of one reference battery 112. The average may be the time average. Then, the reference battery 112 is classified into the group of a bold frame where a row that matches the calculated average SOC and a column that matches the calculated average temperature intersect. The controller 304 performs such processing on the reference batteries 112.

Note that the controller 304 classifies the reference batteries 112 into the groups in the first map MP1 by restricting the reference batteries 112 to those in the vehicles 2 having a high percentage of stops (the inactive current frequency is greater than or equal to the first threshold). That is, the history of the reference batteries 112 other than the reference batteries 112 in the vehicles 2 having a high percentage of stops is not used in generating the first map data M1.

The reference battery 112 in the vehicle 2 having a high percentage of stops is deteriorated mainly due to storage. Therefore, by restricting the history and the degree of deterioration of the reference batteries 112 to those in the vehicles 2 having a high percentage of stops, the controller 304 can generate the first map data M1 by focusing on the degree of storage deterioration and the history that influences the degree of storage deterioration, that is, by isolating the influence of cycle deterioration.

The degree of storage deterioration changes depending on the SOC and temperature. Therefore, the degree of storage deterioration of the reference batteries 112 having similar trends of SOC and temperature are intended to change in similar manners. For this reason, the controller 304 classifies the groups in the first map data M1 by trends of the SOC and temperature.

From the above, in the reference batteries 112 classified into a certain group in the first map data M1, storage deterioration is the predominant type of deterioration, and it is expected that the degree of storage deterioration changes with similar conditions.

Based on the theory that the degree of storage deterioration is due to the formation of a solid electrolyte interphase (SEI) film, if the SOC and the temperature are constant, storage deterioration is known to change with time as indicated by equation (1) as follows:

$$\text{degree of shortage deterioration = storage deterioration coefficient} \times √ \text{t} \qquad \text{(1)}$$

where t is time in units of months.

Therefore, the controller 304 adopts the storage deterioration coefficient, which is the rate of change in the degree of storage deterioration with respect to the square root of time, as a coefficient indicating the rate of change in the degree of deterioration in the first map data M1. Then, the controller 304 obtains the storage deterioration coefficient of each group as follows and registers it in the first map data M1.

FIG. 5 is a diagram explaining an example of a method of deriving a coefficient (storage deterioration coefficient) in the first map data. The storage deterioration coefficient can be obtained by the regression analysis illustrated in FIG. 5 from the history information and the degree of deterioration of the reference batteries 112 classified into one group in the first map data M1. Plots illustrated in FIG. 5 represent the total use time and the degree of deterioration of eight reference batteries 112 that are among the reference batteries 112 in the vehicles 2 having a high percentage of stops and that are classified into a group where the temperature trend is from -35° C. to -25° C. and the voltage trend is from SOC 90% to 100%. A regression line K1 is obtained from the plots. The slope of the regression line K1 represents the storage deterioration coefficient.

Once the storage deterioration coefficient is determined, the controller 304 registers it as a coefficient of the group in the first map data M1 in which the temperature trend is from -35° C. to -25° C. and the voltage trend is from SOC 90% to 100%. The controller 304 performs such calculations for all the groups (all rows and all columns) in the first map data M1 to complete the first map data M1.

### Second Map Data

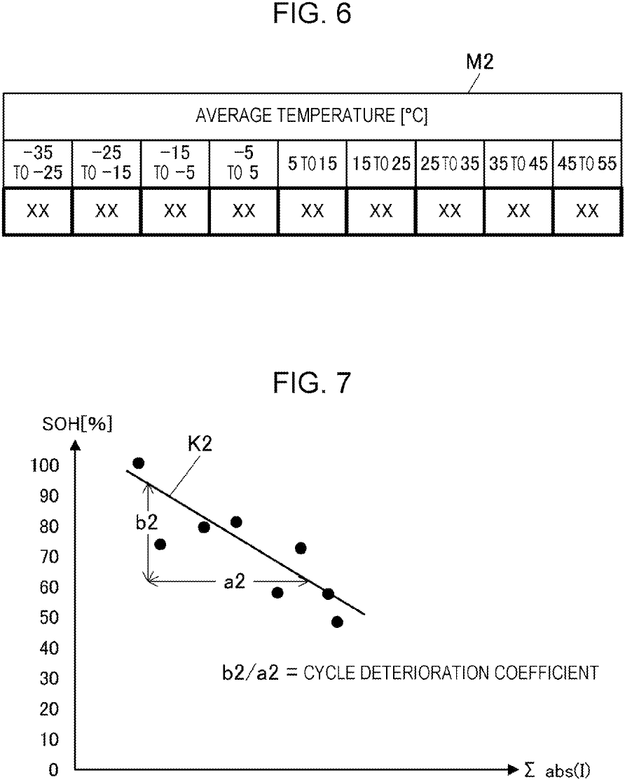

FIG. 6 is a diagram illustrating second map data for obtaining the degree of cycle deterioration.

The second map data M2 is map data for obtaining the degree of cycle deterioration. The second map data M2 is generated by the controller 304 based on the information in the history database 302 and the information in the deterioration degree database 303.

The second map data M2 corresponds to data where groups into which the reference batteries 112 are classified are associated with cycle deterioration coefficients each indicating the rate of change in the degree of deterioration of the reference batteries 112. In FIG. 6, each bold frame corresponds to one group, and the cycle deterioration coefficient of that group is stored within the bold frame. “XX” in FIG. 6 indicates the cycle deterioration coefficient of each group.

The groups in the second map data M2 correspond to the reference batteries 112 classified by trends of a certain group parameter (temperature, which corresponds to an example of a first group parameter according to the disclosure) among types of operation parameters (current, voltage, and temperature) of the reference batteries 112. In the present embodiment, the average temperature is adopted as the trend of temperature. The controller 304 calculates the average temperature from the history information of one reference battery 112. Then, the reference battery 112 is classified into a group of a column that matches the average temperature. The controller 304 performs such processing on the reference batteries 112.

Note that the controller 304 classifies the reference batteries 112 into the groups in the second map MP by restricting the reference batteries 112 to those in the vehicles 2 having a low percentage of stops (the inactive current frequency is less than or equal to the second threshold). That is, the history of the reference batteries 112 other than the reference batteries 112 in the vehicles 2 having a low percentage of stops is not used in generating the second map data M2.

The reference battery 112 in the vehicle 2 having a low percentage of stops is deteriorated mainly due to cycle. Therefore, by restricting the history and the degree of deterioration of the reference batteries 112 to those in the vehicles 2 having a low percentage of stops, the controller 304 can generate the second map data M2 by focusing on the degree of cycle deterioration and the history that influences the degree of cycle deterioration, that is, by isolating the influence of storage deterioration.

The degree of cycle deterioration changes depending on the temperature. Therefore, the degree of cycle deterioration of the reference batteries 112 having similar trends of temperature are intended to change in similar manners. For this reason, the controller 304 classifies the groups in the second map data M2 by trends of temperature.

From the above, in the reference batteries 112 classified into a certain group in the second map data M2, cycle deterioration is the predominant type of deterioration, and it is expected that the degree of cycle deterioration changes with similar conditions.

Since cycle deterioration occurs due to the flow of current regardless of the direction of the current, it is assumed that the degree of cycle deterioration changes according to the current integrated value as indicated in equation (2) as follows:

$$\text{degree of cycle deterioration = cycle deterioration coefficient} \times \sum a b s ( I ) \qquad \text{(2)}$$

where the current integrated value Σabs(I) is the time accumulation of the absolute value of the current history I(t).

Therefore, the controller 304 adopts the cycle deterioration coefficient, which is the rate of change in the degree of cycle deterioration with respect to the current integrated value, as a coefficient indicating the rate of change in the degree of deterioration in the second map data M2. Then, the controller 304 obtains the cycle deterioration coefficient of each group as follows and registers it in the second map data M2.

FIG. 7 is a diagram for explaining an example of a method of deriving a coefficient (cycle deterioration coefficient) in the second map data. The cycle deterioration coefficient can be obtained by the regression analysis illustrated in FIG. 7 from the history information and the degree of deterioration of the reference batteries 112 classified into one group in the second map data M2. Plots illustrated in FIG. 7 represent the current integrated value and the degree of deterioration of eight reference batteries 112 that are among the reference batteries 112 in the vehicles 2 having a low percentage of stops and that are classified into a group where the temperature trend is from -35° C. to -25° C. A regression line K2 is obtained from the plots. The slope of the regression line K2 represents the cycle deterioration coefficient.

Once the cycle deterioration coefficient is determined, the controller 304 registers it as a coefficient of the group in the second map data M2 in which the temperature trend is from -35° C. to -25° C. The controller 304 performs such calculations for all the groups (all columns) in the second map data M2 to complete the second map data M2.

### Weighting Data Table for Degree of Storage Deterioration and Degree of Cycle Deterioration

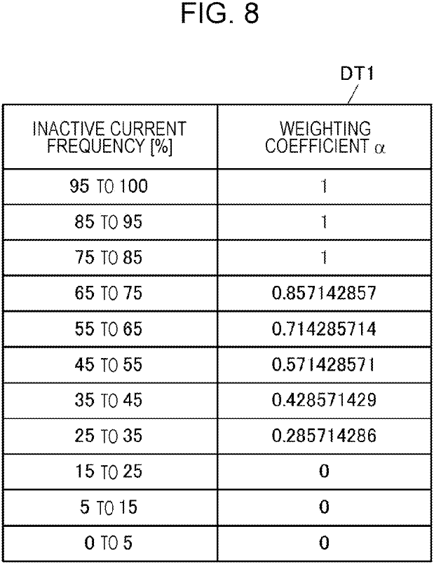

FIG. 8 is a diagram illustrating an example of a weighting data table. If the vehicle 1 has a high percentage of stops and has the target battery 111 whose inactive current frequency is greater than or equal to the first threshold, the type of deterioration of the target battery 111 is predominantly storage deterioration. Therefore, the predicted value of the degree of deterioration of the target battery 111 is almost identical to the predicted value of the degree of storage deterioration.

Meanwhile, if the vehicle 1 has a low percentage of stops and has the target battery 111 whose inactive current frequency is less than or equal to the second threshold, the type of deterioration of the target battery 111 is predominantly cycle deterioration. Therefore, the predicted value of the degree of deterioration of the target battery 111 is almost identical to the predicted value of the degree of cycle deterioration.

In contrast, if the vehicle 1 has a not high or low percentage of stops and has the target battery 111 whose inactive current frequency is a moderate value, storage deterioration as well as cycle deterioration appears in the target battery 111. However, when cycle deterioration is occurring, the progress of storage deterioration becomes small, and when storage deterioration is occurring, cycle deterioration is somewhat restored. Therefore, the degree of deterioration of the target battery 111 is not the simple sum of the degree of storage deterioration and the degree of cycle deterioration, but is the sum obtained with the addition of a weighting coefficient α.

The weighting data table DT1 is a data table in which the above weighting coefficient α and the inactive current frequency are associated with each other. The value of the weighting coefficient α may be obtained by tests or the like, or the value may be obtained theoretically. In the example illustrated in FIG. 8, for the intermediate inactive current frequencies (= 25% to 75%), values calculated from the presence frequency are adopted as the weighting coefficients α. The presence frequency is the percentage of -5 A to 5 A in the current frequency of one vehicle. The current frequency of one vehicle is obtained from the current history information.

### Process of Predicting Degree of Deterioration of Target Battery 111

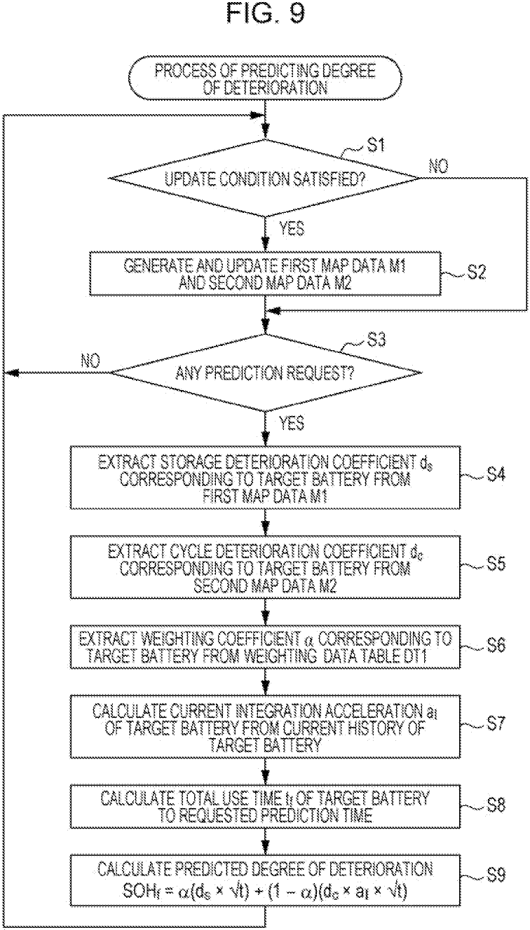

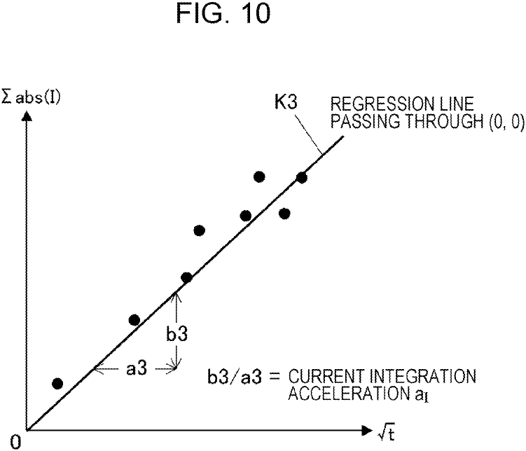

Next, a process of predicting the degree of deterioration of the target battery 111 (estimation of the degree of deterioration in the future) will be described. FIG. 9 is a flowchart illustrating a procedure of the process of predicting the degree of deterioration.

When a certain update condition is satisfied (YES in step S1), the controller 304 generates first map data M1 and updates the first map data M1 to the new one (step S2). Similarly, the controller 304 generates second map data M2 and updates the second map data M2 to the new one (step S2). The method of generating the first map data M1 and the second map data M2 is as described above.

The certain update condition may be appropriately set as, for example, the case in which a certain period of time has elapsed or the amount of added history information has become a certain amount. Note that the update interval may be made longer when the history of the reference batteries 112 has already been sufficiently obtained and, even if the first map data M1 or the second map data M2 is generated again, there is little change from the previous one. Alternatively, subsequent updates may not be performed.

If there is a request for prediction of the degree of deterioration of the target battery 111 (YES in step S3), the controller 304 proceeds with the process of prediction. In the process of prediction, firstly, based on the history of the target battery 111 and the first map data M1, the controller 304 extracts a storage deterioration coefficient dₛ corresponding to the target battery 111 from the first map data M1 (step S4).

In one example, in step S4, the controller 304 first determines to which group in the first map data M1 the target battery 111 belongs from the history information of the target battery 111. In a more specific example, the controller 304 calculates a voltage trend (such as the average SOC) and a temperature trend (such as the average temperature) from the voltage history and temperature history of the target battery 111, and finds a group in the first map data M1 that matches the above trends. Then, the controller 304 extracts a coefficient associated with the group as the storage deterioration coefficient dₛ corresponding to the target battery 111.

Next, based on the history information of the target battery 111 and the second map data M2, the controller 304 extracts a cycle deterioration coefficient d_{c} corresponding to the target battery 111 (step S5).

In one example, in step S5, the controller 304 first determines to which group in the second map data M2 the target battery 111 belongs from the history information of the target battery 111. In a more specific example, the controller 304 calculates a temperature trend (such as the average temperature) from the temperature history of the target battery 111, and finds a group in the second map data M2 that matches the above trend. Then, the controller 304 extracts a coefficient associated with the group as the cycle deterioration coefficient d_{c} corresponding to the target battery 111.

Next, the controller 304 extracts a weighting coefficient α corresponding to the target battery 111 from the weighting data table DT1 (step S6). That is, the controller 304 calculates the inactive current frequency from the current history of the target battery 111, and extracts the weighting coefficient α corresponding to the inactive current frequency from the weighting data table DT1.

Next, the controller 304 obtains a current integration acceleration a_{I} from the history of the target battery 111 (step S7).

FIG. 10 is a diagram illustrating an example of a method of calculating the current integration acceleration. The current integration acceleration a_{I} is a quantity that represents the relationship between the current integrated value and the square root √t of the use time. In the case where the driving trend of the vehicle 1 is constant, the current integrated value Σabs(I) and the use time t are substantially proportional. Meanwhile, since the above-mentioned storage deterioration is expressed as a function of the square root √t of the use time, accordingly the current integrated value Σabs(I) is also expressed here as a function of the square root √t of the use time. Thus, the controller 304 divides the use time of the target battery 111 into plural periods, and calculates each current integrated value ∑abs (I) from the beginning to the end of each period, thereby obtaining plots of the graph illustrated in FIG. 10. Then, the controller 304 performs a regression analysis from the plots to obtain a regression line K3 on the graph between the current integrated value Σabs(I) and the square root √t of time, and obtains the slope of the regression line K3 as the current integration acceleration a_{I}. Because the current integrated value Σabs(I) = 0 when the use time t = 0, the regression line K3 may be calculated to pass through the origin (0, 0).

Next, the controller 304 calculates the use time t_{f} of the target battery 111 from the first use point (start of use) of the target battery 111 to a requested prediction time point (step S8). The use time t_{f} may be referred to as the cumulative use time up to the prediction time point.

Note that the calculations in steps S4 to S8 may be performed in any order.

Then, the controller 304 calculates a degree of overall deterioration SOH_{f} of the target battery 111 in the future (prediction time point) as indicated by equation (3) as follows (step S9):

$$\begin{matrix}{\text{SOH}}_{\text{f}} = α ( {\text{storage deterioration coefficient d}}_{\text{s}} \times √ {\text{t}}_{\text{f}} ) + \\ ( 1 - α ) ( {\text{cycle deterioration coefficient d}}_{\text{c}} \times \text{current integration} \\ {\text{acceleration a}}_{\text{I}} \times √ {\text{t}}_{\text{f}} )\end{matrix} \qquad \text{(3)}$$

In equation (3), the first term “α(storage deterioration coefficient dₛ × √t_{f})” on the right side represents the degree of storage deterioration at the prediction time point (time point in the use time t_{f}). Also, “current integration acceleration a_{I} × √t_{f}” in the second term on the right side represents the predicted value of the current integrated value Σabs(I) at the prediction time point (time point in the use time t_{f}). Therefore, the second term “(1-α) (cycle deterioration coefficient d_{c} × current integration acceleration a_{I} × √t_{f})” on the right side represents the degree of cycle deterioration at the prediction time point (time point in the use time t_{f}).

Then, the controller 304 ends the process of predicting the degree of deterioration at one time and returns the process to step S1.

The program P1 of the above-described process of predicting the degree of deterioration is stored in the storage unit 305 (non-transitory computer readable medium) of the battery deterioration degree prediction apparatus 300. The controller 304 may be configured to read a program stored in a portable non-transitory recording medium and execute the program. The above-mentioned portable non-transitory storage medium may store the program P1 of the above-mentioned process of predicting the degree of deterioration.

The battery deterioration degree prediction apparatus 300 may send the predicted degree of future deterioration SOH_{f} of the target battery 111 to the vehicle 1 and to the owner, management company, manufacturer, and the like of the vehicle 1, and the degree of deterioration SOH_{f} may be displayed and output. Depending on the predicted degree of deterioration SOH_{f}, the owner, management company or manufacturer of the vehicle 1 can grasp the future transition of the degree of deterioration of the target battery 111 and schedule maintenance of the target battery 111.

As described above, according to the battery deterioration degree prediction apparatus 300 of the present embodiment, the history and degree of deterioration of the reference batteries 112 provided in the vehicles 2 are obtained, and the degree of deterioration of the target battery 111 is predicted based on these obtained items of data. The history and degree of deterioration of the reference batteries 112 are data reflecting various actual usage states of the vehicles 2 and the reference batteries 112. Therefore, by using these items of data, the degree of deterioration that corresponds to the actual usage state can also be predicted for the target battery 111.

Furthermore, according to the battery deterioration degree prediction apparatus 300, the controller 304 uses the first map data M1 in which, from the history and degree of deterioration of the reference batteries 112, the rate of change (storage deterioration coefficient) in the degree of deterioration for each of the groups into which the reference batteries 112 are classified is registered. Furthermore, as the groups in the first map data M1, groups classified by trends of voltage and temperature among the operation parameters (current, voltage, and temperature) of the reference batteries 112 are adopted. Since the degree of storage deterioration depends on the voltage (SOC) and temperature, the reference batteries 112 having similar voltage trends and temperature trends are grouped together and the rate of change in the degree of deterioration corresponding to each group is assigned, an appropriate rate of change in the degree of storage deterioration can be obtained using the first map data M1.

Similarly, according to the battery deterioration degree prediction apparatus 300, the controller 304 uses the second map data M2 in which, from the history and degree of deterioration of the reference batteries 112, the rate of change (cycle deterioration coefficient) in the degree of deterioration for each of the groups into which the reference batteries 112 are classified is registered. Furthermore, as the groups in the second map data M2, groups classified by trends of temperature among the operation parameters (current, voltage, and temperature) of the reference batteries 112 are adopted. Since the degree of cycle deterioration depends on the temperature, the reference batteries 112 having similar temperature trends are grouped together and the rate of change in the degree of deterioration corresponding to each group is assigned, an appropriate rate of change in the degree of cycle deterioration can be obtained using the second map data M2.

Furthermore, according to the battery deterioration degree prediction apparatus 300, there is provided the weighting data table DT1 in which the inactive current frequency is associated with the weighting coefficient α, and the degree of overall deterioration (SOH) is predicted based on the storage deterioration coefficient extracted from the first map data M1, the cycle deterioration coefficient extracted from the second map data M2, and the weighting coefficient α. Therefore, the degree of deterioration including both the degree of storage deterioration and the degree of cycle deterioration can be predicted with high accuracy.

The embodiment of the disclosure has been described so far. However, the disclosure is not limited to the above embodiment. For example, the above embodiment has discussed an example in which the average value of the operation parameters used in classifying the reference batteries 112 into groups is applied as the trend of the history of the operation parameters. However, as the trend of the history of the operation parameters, an index that can represent a more detailed history trend may be used. In the above embodiment, the battery deterioration degree prediction apparatus 300 has been described as an apparatus (such as a server apparatus) disposed separately from the vehicles 1 and 2. However, the battery deterioration degree prediction apparatus 300 may be provided in the vehicles 1 and 2. Moreover, the battery deterioration degree prediction apparatus 300 may be composed of plural computers distributed at plural locations. In that case, the history database 302 and the deterioration degree database 303 may be provided in a server apparatus at a distance from the vehicles 1 and 2, and the controller 304 for predicting the degree of deterioration may be provided in the vehicles 1 and 2. Other details discussed in the embodiment, such as the current range H1 (FIG. 3) for determining the inactive current frequency, the first threshold and the second threshold for determining a high or low percentage of stops, and specific examples of the weighting coefficient α, may be modified appropriately without departing from the gist of the disclosure.

According to the disclosure, the history and the degree of deterioration of reference batteries, each of which is a battery for traveling provided in another vehicle, are obtained, and the degree of deterioration of a target battery is predicted using the obtained history and degree of deterioration. Because the history and the degree of deterioration of the reference batteries are data reflecting various actual usage states of the vehicles and the batteries for traveling, by using these items of data, the degree of deterioration that corresponds to the actual usage state can also be predicted for the target battery. In the map data, the rate of change in the degree of deterioration is indicated for each of the groups classified by trends of the history of the first group parameter. Therefore, the controller is able to predict the degree of deterioration of the target battery by using the trend of the history of the first group parameter of the target battery, that is, the rate of change in the degree of deterioration of a group having similar actual usage states. Therefore, the degree of deterioration of the target battery can be predicted with high accuracy.

The controller 304 illustrated in FIG. 1 can be implemented by circuitry including at least one semiconductor integrated circuit such as at least one processor (e.g., a central processing unit (CPU)), at least one application specific integrated circuit (ASIC), and/or at least one field programmable gate array (FPGA). At least one processor can be configured, by reading instructions from at least one machine readable tangible medium, to perform all or a part of functions of the controller 304. Such a medium may take many forms, including, but not limited to, any type of magnetic medium such as a hard disk, any type of optical medium such as a CD and a DVD, any type of semiconductor memory (i.e., semiconductor circuit) such as a volatile memory and a non-volatile memory. The volatile memory may include a DRAM and a SRAM, and the non-volatile memory may include a ROM and a NVRAM. The ASIC is an integrated circuit (IC) customized to perform, and the FPGA is an integrated circuit designed to be configured after manufacturing in order to perform, all or a part of the functions of the modules illustrated in FIG. 1. The controller 304 and at least a part of the communicator 301 (obtaining unit) illustrated in FIG. 1 may be implemented by the circuitry.

1. A battery deterioration degree prediction apparatus comprising:
an obtaining unit configured to obtain a history of types of operation parameters for a target battery, histories of the types of operation parameters for reference batteries, and degrees of deterioration of the reference batteries, the target battery being a battery for traveling provided in a target vehicle, the reference batteries each being a battery for traveling provided in a vehicle different from the target vehicle; and
a controller configured to predict a degree of deterioration of the target battery, wherein
the controller is configured to predict the degree of deterioration of the target battery using map data in which groups into which the reference batteries are classified and coefficients representing rates of change in the degrees of deterioration of the reference batteries are associated with each other,
the groups in the map data are classified by a trend of histories of a first group parameter included in the types of operation parameters, and
the coefficients in the map data are derived based on the histories for the reference batteries and the degrees of deterioration of the reference batteries belonging to one of the groups that is associated with the coefficients.

2. The battery deterioration degree prediction apparatus according to claim 1, wherein the controller is configured to
extract, from the map data, a coefficient associated with one of the groups that matches a trend of the history of the first group parameter of the target battery, and
predict the degree of deterioration of the target battery based on the extracted coefficient.

3. The battery deterioration degree prediction apparatus according to claim 1, wherein
the degree of deterioration of each of the target battery and the reference batteries includes a degree of cycle deterioration representing deterioration due to charging/discharging, a degree of storage deterioration representing deterioration during storage, and a degree of overall deterioration combining the degree of cycle deterioration and the degree of storage deterioration,
the map data includes first map data in which a coefficient indicating a rate of change in the degree of storage deterioration is registered,
the first map data is calculated based on one or more histories of one or more of the reference batteries that has inactive current frequency limited to a first threshold or greater, and
the first group parameter includes temperature and voltage.

4. The battery deterioration degree prediction apparatus according to claim 2, wherein
the degree of deterioration of each of the target battery and the reference batteries includes a degree of cycle deterioration representing deterioration due to charging/discharging, a degree of storage deterioration representing deterioration during storage, and a degree of overall deterioration combining the degree of cycle deterioration and the degree of storage deterioration,
the map data includes first map data in which a coefficient indicating a rate of change in the degree of storage deterioration is registered,
the first map data is calculated based on one or more histories of one or more of the reference batteries that has inactive current frequency limited to a first threshold or greater, and
the first group parameter includes temperature and voltage.

5. The battery deterioration degree prediction apparatus according to claim 1, wherein
the degree of deterioration of each of the target battery and the reference batteries includes a degree of cycle deterioration representing deterioration due to charging/discharging, a degree of storage deterioration representing deterioration during storage, and a degree of overall deterioration combining the degree of cycle deterioration and the degree of storage deterioration,
the map data includes second map data in which a coefficient indicating a rate of change in the degree of cycle deterioration is registered,
the second map data is calculated based on one or more histories of one or more of the reference batteries that has inactive current frequency limited to a second threshold or less, and
the first group parameter includes temperature.

6. The battery deterioration degree prediction apparatus according to claim 2, wherein
the degree of deterioration of each of the target battery and the reference batteries includes a degree of cycle deterioration representing deterioration due to charging/discharging, a degree of storage deterioration representing deterioration during storage, and a degree of overall deterioration combining the degree of cycle deterioration and the degree of storage deterioration,
the map data includes second map data in which a coefficient indicating a rate of change in the degree of cycle deterioration is registered,
the second map data is calculated based on one or more histories of one or more of the reference batteries that has inactive current frequency limited to a second threshold or less, and
the first group parameter includes temperature.

7. The battery deterioration degree prediction apparatus according to claim 3, wherein
the degree of deterioration of each of the target battery and the reference batteries includes a degree of cycle deterioration representing deterioration due to charging/discharging, a degree of storage deterioration representing deterioration during storage, and a degree of overall deterioration combining the degree of cycle deterioration and the degree of storage deterioration,
the map data includes second map data in which a coefficient indicating a rate of change in the degree of cycle deterioration is registered,
the second map data is calculated based on one or more histories of one or more of the reference batteries that has inactive current frequency limited to a second threshold or less, and
the first group parameter includes temperature.

8. The battery deterioration degree prediction apparatus according to claim 4, wherein
the degree of deterioration of each of the target battery and the reference batteries includes a degree of cycle deterioration representing deterioration due to charging/discharging, a degree of storage deterioration representing deterioration during storage, and a degree of overall deterioration combining the degree of cycle deterioration and the degree of storage deterioration,
the map data includes second map data in which a coefficient indicating a rate of change in the degree of cycle deterioration is registered,
the second map data is calculated based on one or more histories of one or more of the reference batteries that has inactive current frequency limited to a second threshold or less, and
the first group parameter includes temperature.

9. The battery deterioration degree prediction apparatus according to claim 1, wherein
the degree of deterioration of each of the target battery and the reference batteries includes a degree of cycle deterioration representing deterioration due to charging/discharging, a degree of storage deterioration representing deterioration during storage, and a degree of overall deterioration combining the degree of cycle deterioration and the degree of storage deterioration,
the map data includes first map data for obtaining a degree of storage deterioration and second map data for obtaining a degree of cycle deterioration, and
the controller is configured to
have a data table indicating a relationship among an inactive current frequency of the target battery, a weighting coefficient for the degree of storage deterioration, and a weighting coefficient for the degree of cycle deterioration, and
predict the degree of overall deterioration of the target battery based on a coefficient extracted from the first map data, a coefficient extracted from the second map data, and the weighting coefficient for the degree of storage deterioration and the weighting coefficient for the degree of cycle deterioration.

10. The battery deterioration degree prediction apparatus according to claim 2, wherein
the degree of deterioration of each of the target battery and the reference batteries includes a degree of cycle deterioration representing deterioration due to charging/discharging, a degree of storage deterioration representing deterioration during storage, and a degree of overall deterioration combining the degree of cycle deterioration and the degree of storage deterioration,
the map data includes first map data for obtaining a degree of storage deterioration and second map data for obtaining a degree of cycle deterioration, and
the controller is configured to
have a data table indicating a relationship among an inactive current frequency of the target battery, a weighting coefficient for the degree of storage deterioration, and a weighting coefficient for the degree of cycle deterioration, and
predict the degree of overall deterioration of the target battery based on a coefficient extracted from the first map data, a coefficient extracted from the second map data, and the weighting coefficient for the degree of storage deterioration and the weighting coefficient for the degree of cycle deterioration.

11. The battery deterioration degree prediction apparatus according to claim 3, wherein
the map data further includes second map data for obtaining the degree of cycle deterioration, and
the controller is configured to
have a data table indicating a relationship among an inactive current frequency of the target battery, a weighting coefficient for the degree of storage deterioration, and a weighting coefficient for the degree of cycle deterioration, and
predict the degree of overall deterioration of the target battery based on a coefficient extracted from the first map data, a coefficient extracted from the second map data, and the weighting coefficient for the degree of storage deterioration and the weighting coefficient for the degree of cycle deterioration.

12. The battery deterioration degree prediction apparatus according to claim 4, wherein
the map data further includes second map data for obtaining the degree of cycle deterioration, and
the controller is configured to
have a data table indicating a relationship among an inactive current frequency of the target battery, a weighting coefficient for the degree of storage deterioration, and a weighting coefficient for the degree of cycle deterioration, and
predict the degree of overall deterioration of the target battery based on a coefficient extracted from the first map data, a coefficient extracted from the second map data, and the weighting coefficient for the degree of storage deterioration and the weighting coefficient for the degree of cycle deterioration.

13. The battery deterioration degree prediction apparatus according to claim 5, wherein
the map data further includes first map data for obtaining the degree of storage deterioration, and
the controller is configured to
have a data table indicating a relationship among an inactive current frequency of the target battery, a weighting coefficient for the degree of storage deterioration, and a weighting coefficient for the degree of cycle deterioration, and
predict the degree of overall deterioration of the target battery based on a coefficient extracted from the first map data, a coefficient extracted from the second map data, and the weighting coefficient for the degree of storage deterioration and the weighting coefficient for the degree of cycle deterioration.

14. The battery deterioration degree prediction apparatus according to claim 6, wherein
the map data further includes first map data for obtaining the degree of storage deterioration, and
the controller is configured to
have a data table indicating a relationship among an inactive current frequency of the target battery, a weighting coefficient for the degree of storage deterioration, and a weighting coefficient for the degree of cycle deterioration, and
predict the degree of overall deterioration of the target battery based on a coefficient extracted from the first map data, a coefficient extracted from the second map data, and the weighting coefficient for the degree of storage deterioration and the weighting coefficient for the degree of cycle deterioration.

15. The battery deterioration degree prediction apparatus according to claim 7, wherein
the controller is configured to
have a data table indicating a relationship among an inactive current frequency of the target battery, a weighting coefficient for the degree of storage deterioration, and a weighting coefficient for the degree of cycle deterioration, and
predict the degree of overall deterioration of the target battery based on a coefficient extracted from the first map data, a coefficient extracted from the second map data, and the weighting coefficient for the degree of storage deterioration and the weighting coefficient for the degree of cycle deterioration.

16. The battery deterioration degree prediction apparatus according to claim 8, wherein
the controller is configured to
have a data table indicating a relationship among an inactive current frequency of the target battery, a weighting coefficient for the degree of storage deterioration, and a weighting coefficient for the degree of cycle deterioration, and
predict the degree of overall deterioration of the target battery based on a coefficient extracted from the first map data, a coefficient extracted from the second map data, and the weighting coefficient for the degree of storage deterioration and the weighting coefficient for the degree of cycle deterioration.

17. A battery deterioration degree prediction apparatus comprising circuitry configured to:
obtain a history of types of operation parameters for a target battery, histories of the types of operation parameters for reference batteries, and degrees of deterioration of the reference batteries, the target battery being a battery for traveling provided in a target vehicle, the reference batteries each being a battery for traveling provided in a vehicle different from the target vehicle; and
predict a degree of deterioration of the target battery, wherein
the circuitry is configured to predict the degree of deterioration of the target battery using map data in which groups into which the reference batteries are classified and coefficients representing rates of change in the degrees of deterioration of the reference batteries are associated with each other,
the groups in the map data are classified by a trend of histories of a first group parameter included in the types of operation parameters, and
the coefficients in the map data are derived based on the histories for the reference batteries and the degrees of deterioration of the reference batteries belonging to one of the groups that is associated with the coefficients.
